(19) United States
(12) Patent Application Publication
(10) Pub. No.: US 2008/0309436 A1
(43) Pub. Date: Dec. 18, 2008

(54) MULTI-INPUT MULTI-OUTPUT AMPLIFIER, AN ACTIVE INDUCTOR, A FILTER AND A RADIO COMMUNICATION DEVICE

(75) Inventors: Takafumi Yamaji, Yokohama-shi (JP); Rui Ito, Chigasaki-shi (JP); Tetsuro Itakura, Tokyo (JP)

Correspondence Address: AMIN, TUROCY & CALVIN, LLP, 127 Public Square, 57th Floor, Key Tower, CLEVELAND, OH, 44114, US

(73) Assignee: Kabushiki Kaisha Toshiba, Tokyo (JP)

(21) Appl. No.: 12/051,098

(22) Filed: Mar. 19, 2008

(30) Foreign Application Priority Data
Jun. 13, 2007 (JP) 2007-156580

(51) Int. Cl. H03H 11/00; H03F 3/00; H04L 25/00

(52) U.S. Cl. 333/214; 330/147; 330/148; 375/261

(57) ABSTRACT

A non-inverting amplifier includes n external input terminals which receive n (n≧3) input voltage signals having a constant sum of voltages, respectively, n amplification units each including n−1 internal input terminals connected to n−1 terminals of the n external input terminals in a different combination for each of the amplification units, n−1 voltage-to-current converters which convert input voltage signals from the internal input terminals into current signals, and a load which converts an added current signal obtained by adding up the current signals into an output voltage signal, and n external output terminals which output n output voltage signals from the n amplification units.

### CROSS-REFERENCE TO RELATED APPLICATIONS

This application is based upon and claims the benefit of priority from prior Japanese Patent Application No. 2007-156580, filed Jun. 13, 2007, the entire contents of which are incorporated herein by reference.

### BACKGROUND OF THE INVENTION

1. Field of the Invention

This invention relates to a multi-input multi-output amplifier which especially handles an analog vector signal such as a complex number signal, and an active inductor, a filter and a radio communication device using the above amplifier.

2. Description of the Related Art

In a radio communication field as of 2005, there are adopted many systems for modulating both an amplitude and a phase of a signal. Therefore, in many cases, two orthogonal signals are used which are referred to as an in-phase signal (I-signal) and a quadrature-phase signal (Q-signal).

For example, in a case where a filter is formed, for example, on an integrated circuit as of around 1995, a single-ended system (circuit system in which a voltage between a signal line and the ground is handled as the signal) is adopted for both the I-signal and the Q-signal. An example of a filter of the single-ended system is described in “A 2.5-V active low-pass filter using all-n-p-n Gilbert cells with a 1-Vp-p range”, authored by M. Koyama, T. Arai, H. Tanimoto, and Y. Yoshida, IEEE Journal of Solid-State Circuits, Vol. 28, No. 12, December 1993, pp. 1246 to 1253.

Since 2000, there has been increasingly adopted a differential system (circuit system in which a voltage between a positive signal line and a negative signal line is handled as the signal) for both the I-signal and the Q-signal. An example of a filter of the differential system is disclosed in “A 2.7-V, 200-kHz, 49-dBm, stopband-IIP3, low-noise, fully balanced gm-C filter IC”, authored by T. Itakura, T. Ueno, H. Tanimoto, A. Yasuda, R. Fujimoto, T. Arai, and H. Kokatsu, IEEE Journal of Solid-State Circuits, Vol. 34, No. 8, August 1999, pp. 1155 to 1159.

An advantage of the single-ended system is that components are less than those of the differential system. Since a communication system in the 1990s has a low transmission rate, and requires a plurality of capacitors, several capacitors are mounted as external components of the integrated circuit on a circuit board. When the external components are as few as possible, costs are reduced. Therefore, the single-ended system is preferable.

However, in the single-ended system, separately from a power voltage and a ground potential, an analog ground potential needs to be supplied as an analog reference voltage to each amplifier in the integrated circuit. In this case, since a signal current flows into the analog ground potential, it is necessary to use an analog ground buffer amplifier having a high current driving capability (current supply capability and/or current absorbing capability). When an output impedance of the buffer amplifier is high, the analog ground potential varies with the signal current. This variation causes, for example, signal leakage from the I-signal into the Q-signal, or signal leakage from output into input. The latter signal leakage causes a problem of oscillation of the circuit.

Since 2000, in a radio communication system, a band has been broadened for high-speed data transmission. Therefore, a capacitor having a comparatively small capacity is being used. Most of components can be integrated on a chip, and accordingly the differential system has been increasingly adopted. In the differential system, a positive terminal and a negative terminal are loaded with voltages having an equal size and reverse polarities, respectively, to perform amplification or the like. An average value of the voltages of the positive and negative terminals virtually plays a role of the analog ground potential. Since the current output from the positive terminal flows into the negative terminal, no analog ground terminal has to be prepared. Since the differential system does not require the analog ground buffer amplifier required for the single-ended system, power consumption of the differential system becomes smaller than that of the single-ended system. Therefore, at present, the differential system is adopted in most cases.

As the cost per unit area of a semiconductor chip rises with development of a semiconductor fine processing technology, an analog circuit, especially, a passive element in the analog circuit occupies a large ratio of a chip area. Therefore, reduction of the area occupied by the passive element in the semiconductor chip is an important problem for cost reduction.

The single-ended system is advantageous for the reductions of the chip area and the cost in that there are fewer components. On the other hand, in the single-ended system, since the analog ground potential is supplied to each circuit block as described above, the analog ground buffer amplifier having a high current driving capability is required, and therefore, power consumption increases.

The differential system does not require the analog ground buffer amplifier required for the single-ended system, and the differential system has an advantage that the power consumption is reduced. On the other hand, the components of the differential system are more than those of the single-ended system, and the cost increases in the differential system.

In JP-A 2007-043489 (KOKAI), there is disclosed an amplifier having an amplification unit which amplifies a plurality of input signals (e.g., balanced three-phase signals), respectively, to obtain a plurality of output signals, and a common mode gain reduction circuit in which a common mode gain of a common mode output as an average of the output signals with respect to a common mode input as an average of the input signals is set to be smaller than a differential mode gain of a plurality of differential mode outputs as a difference between each output signal and the common mode output with respect to a differential mode input as a difference between each input signal and the common mode input.

In the amplifier of JP-A 2007-043489 (KOKAI), for example, a two-dimensional signal is referred to as a balanced three-phase signal to perform amplification, and a common mode gain reduction circuit as mentioned above is disposed, whereby any analog ground potential does not have to be supplied in the same manner as in the differential system, and the number of components can be more reduced than in the differential system.

In the differential system, the signal line is replaced to easily realize an inverting amplifier and a non-inverting amplifier. On the other hand, the amplifier of JP-A 2007-043489 (KOKAI) can amplify a balanced multiphase signal such as the balanced three-phase signal, but it becomes the inverting amplifier in the case of the single-ended system.

A use application of the amplifier requires the non-inverting amplifier, and it is demanded that the amplifier which amplifies the balanced multiphase signal can be realized also as the non-inverting amplifier. If two stages of the amplifiers according to JP-A 2007-043489 (KOKAI) are used, the non-inverting amplifier can be realized. However, the increase of the amplification stages not only increases of a power consumption but also limits an operating frequency in order to secure stability of the circuit.

### BRIEF SUMMARY OF THE INVENTION

According to one aspect of the present invention, there is provided a non-inverting amplifier comprising: n external input terminals which receive n (n≧3) input voltage signals having a constant sum of voltages, respectively; n amplification units each including: n−1 internal input terminals connected to n−1 terminals of the n external input terminals in a different combination for each of the amplification units; n−1 voltage-to-current converters which convert input voltage signals from the internal input terminals into current signals; and a load which converts an added current signal obtained by adding up the current signals into an output voltage signal; and n external output terminals which output n output voltage signals from the n amplification units.

### BRIEF DESCRIPTION OF THE SEVERAL VIEWS OF THE DRAWING

FIG. 1 is a circuit diagram showing a three-input three-output non-inverting amplifier according to a first embodiment;

FIG. 2 is a block diagram showing a four-input four-output non-inverting amplifier according to a second embodiment;

FIG. 3 is an explanatory view of a three-dimensional vector space;

FIG. 4 is a circuit diagram showing a three-input three-output non-inverting amplifier according to a third embodiment;

FIG. 5 is a block diagram showing a three-input three-output inverting amplifier having a two-stage constitution according to a fourth embodiment;

FIG. 6 is a circuit diagram showing a specific example of the inverting amplifier for use in the fourth embodiment;

FIG. 7 is a circuit diagram showing an active inductor according to a fifth embodiment;

FIG. 8 is a diagram showing a Y-type equivalent circuit of the active inductor shown in FIG. 7;

FIG. 9 is a diagram showing a A-type equivalent circuit of the active inductor shown in FIG. 7;

FIG. 10 is a diagram showing a filter (a resonance circuit) according to a sixth embodiment;

FIG. 11 is a diagram showing a A-type equivalent circuit of the filter in FIG. 10; and

FIG. 12 is a block diagram showing a radio communication device according to a seventh embodiment.

### DETAILED DESCRIPTION OF THE INVENTION

Hereinafter, several embodiments of the present invention will be described in detail with reference to the drawings.

### First Embodiment

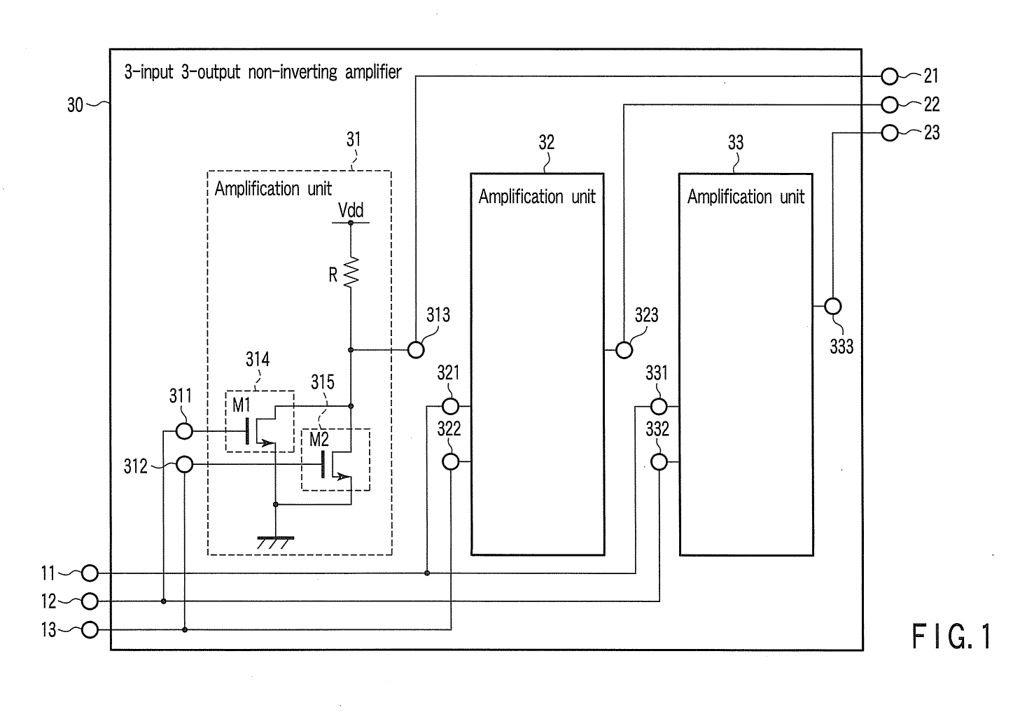

FIG. 1 shows an n-input n-output non-inverting amplifier according to a first embodiment of the present invention, specifically a three-input three-output non-inverting amplifier 30. That is, the present embodiment is an example of n=3. The amplifier 30 includes three external input terminals 11, 12 and 13, three external output terminals 21, 22 and 23, and three amplification units 31, 32 and 33. Into the external input terminals 11, 12 and 13, input voltage signals Va, Vb and Vc having a constant average value ((Va+Vb+Vc)/3) of voltages is are input. In the present embodiment, such input voltage signals Va, Vb and Vc are referred to as balanced three-phase signals.

The amplification units 31, 32 and 33 include n−1=2 internal input terminals and one internal output terminal. That is, the amplification unit 31 includes internal input terminals 311 and 312 and an internal output terminal 313, the amplification unit 32 includes internal input terminals 321 and 322, and an internal output terminal 323, and the amplification unit 33 includes internal input terminals 331 and 332, and an internal output terminal 333.

The internal input terminals of each of the amplification units 31, 32 and 33 are connected to n−1=2 terminals of the external input terminals 11, 12 and 13 in a different combination for each of the amplification units 31, 32 and 33. For example, the internal input terminals 311 and 312 of the amplification unit 31 are connected to the external input terminals 12 and 13, the internal input terminals 321 and 322 of the amplification unit 32 are connected to the external input terminals 11 and 13, and the internal input terminals 331 and 332 of the amplification unit 33 are connected to the external input terminals 11 and 12. Therefore, the input voltage signals Vb and Vc of the input voltage signals Va, Vb and Vc are input into the amplification unit 31, Va and Vc are input into the amplification unit 32, and Va and Vb are input into the amplification unit 33.

Two input voltage signals input into each of the amplification units 31, 32 and 33 are converted into currents by a voltage-to-current converter to further add up the currents. For example, the amplification unit 31 includes voltage-to-current converters 314 and 315 and a load R. In the example of FIG. 1, N-type MOS transistors M1 and M2 are used in the voltage-to-current converters 314 and 315. The gates of transistors M1 and M2 are connected to the internal input terminals 311 and 312, the sources thereof are connected to the ground as a reference potential point, and the drains thereof are connected in common to the internal output terminal 313, and connected to a power source Vdd via the load R. Therefore, transistors M1 and M2 form a grounded source amplifier together with the load R.

The input voltage signals Vb and Vc are converted into current signals by the voltage-to-current converters 314 and 315, respectively. Output terminals (the drains of transistors M1 and M2) of the voltage-to-current converters 314 and 315 are connected to each other, whereby the current signals output from the voltage-to-current converters 314 and 315 are added. The added current signal obtained by adding up the current signals is converted into a voltage signal (the output voltage signal) by the load R, and led to the internal output terminal 313. Here, a resistor is used as the load R, but an active load such as a current mirror circuit may be used.

The amplification units 32 and 33 are configured in the same manner as in the amplification unit 31. Therefore, in the amplification unit 32, an added current signal in which current signals obtained by voltage-to-current conversion of the input voltage signals Va and Vc are added is converted into an output voltage signal, and led to the internal output terminal 323. Similarly, in the amplification unit 33, an added current signal in which current signals obtained by voltage-to-current conversion of the input voltage signals Va and Vb are added is converted into an output voltage signal, and led to the internal output terminal 333. The output voltage signals from the internal output terminals 313, 323 and 333 of the amplification units 31, 32 and 33 are led to the external output terminals 21, 22 and 23.

In a differential system, an average value of the two input signals is obtained as a virtual reference potential (an analog ground), with regard to the balanced three-phase signals as the input voltage signals Va, Vb and Vc input into the non-inverting amplifier 30 of FIG. 1, an average value of the three signals is similarly obtained as a virtual reference potential. That is, the average value of the voltages Va, Vb and Vc is a reference potential (a O-potential in general). This average value is (Va+Vb+Vc)/3=0, that is, the sum of Va, Vb and Vc is Va+Vb+Vc=0. In the present embodiment, such characteristics of the balanced three-phase signal are noted, and Vb+Vc is used as an inverted signal −Va of Va. Similarly, Va+Vc is used as an inverted signal −Vb of Vb, and Va+Vb is used as an inverted signal −Vc of Vc.

A basic amplifier using a treatment is an inverting amplifier typified by a grounded source amplifier or a grounded emitter amplifier. However, when an active inductor or the like is realized as described later, a non-inverting amplifier is sometimes required. A differential amplifier which amplifies a differential signal (a balanced two-phase signal) can realize either the inverting amplifier or the non-inverting amplifier by replacement of a signal lines. However, a method for realizing a multi-input multi-output non-inverting amplifier which handles a balanced multiphase signal such as a balanced three-phase signal is not known. As described above, in a case where two stages of multi-input multi-output amplifiers disclosed in JP-A 2007-043489 (KOKAI) are connected, such a non-inverting amplifier can be realized, but a power consumption increases in the two-stage amplifier, and it is difficult to realize a broadband for securing stability.

In the non-inverting amplifier 30 of the present embodiment shown in FIG. 1, as described above, by use of a characteristic that the average value of the input voltage signals Va, Vb and Vc is (Va+Vb+Vc)/3=0, that is, the sum is constant at Va+Vb+Vc=0, the amplification units 31, 32 and 33 amplify −Va=Vb+Vc, −Vb=Va+Vc and −Vc=Va+Vb, respectively. In the example of FIG. 1, each of the amplification units 31, 32 and 33 forms a source grounded amplifier including the MOS transistors M1 and M2 and the load R, and hence functions as the inverting amplifier which inverts the phase of the input voltage signal to amplify the signal. Therefore, as the output voltage signals of the amplification units 31, 32 and 33, signals kVa, kVb and kVc (with the proviso that k is an amplification factor, and a positive real number), that is, in-phase voltage signals of the input voltage signals Va, Vb and Vc are obtained, so that the whole amplifier 30 of FIG. 1 functions as a three-input three-output non-inverting amplifier.

Thus, according to the present embodiment, the non-inverting amplifier 30 with respect to the balanced three-phase signal can be realized with one stage of constitution. Therefore, when this non-inverting amplifier 30 is used, a three-terminal active inductor capable of realizing a broadband and reducing a power consumption can be realized. Furthermore, a three-terminal filter using the three-terminal active inductor can be realized. In FIG. 1, the MOS transistor is used, but needless to say, the MOS transistor may be replaced with a bipolar transistor. In this case, the base, collector and emitter of the bipolar transistor correspond respectively to the gate, drain and source of the MOS transistor. Thus, the MOS transistor and the bipolar transistor are compatible with each other, and this also applies to the following embodiments. The gate and base are sometimes generically referred to as control terminals, and the drain and collector are sometimes generically referred to as first main terminals, and the source and emitter are sometimes generically referred to as second main terminals.

### Second Embodiment

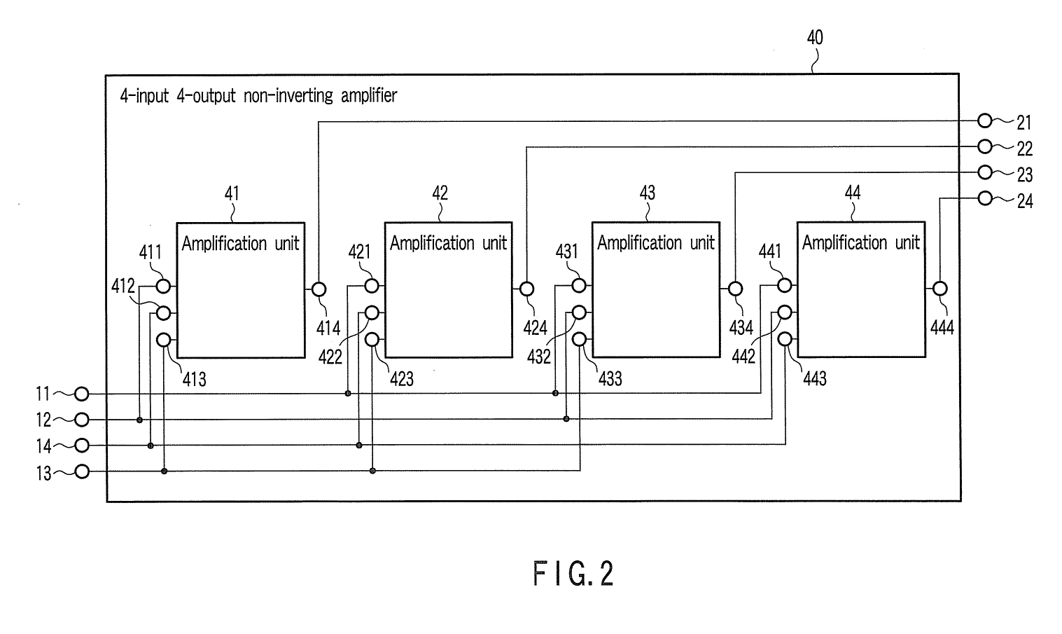

FIG. 2 shows a four-input four-output non-inverting amplifier 40 (n=4) according to a second embodiment of the present invention. The amplifier 40 includes four external input terminals 11, 12, 13 and 14, four external output terminals 21, 22, 23 and 24, and four amplification units 41, 42, 43 and 44. Input voltage signals (Va, Vb, Vc and Vd) having a constant average value are input into the external input terminals 11, 12, 13 and 14.

The amplification units 41, 42, 43 and 44 include n−1=3 internal input terminals and one internal output terminal. That is, internal input terminals of each of the amplification units 41, 42, 43 and 44 are connected to n−1=3 terminals of the external input terminals 11, 12, 13 and 14 in a different combination for each of the amplification units 41, 42, 43 and 44. That is, internal input terminals 411, 412 and 413 of the amplification unit 41 are connected to the external input terminals 12, 13 and 14, internal input terminals 421, 422 and 423 of the amplification unit 42 are connected to the external input terminals 11, 13 and 14, internal input terminals 431, 432 and 433 of the amplification unit 43 are connected to the external input terminals 11, 12, and 14, and internal input terminals 441, 442 and 443 of the amplification unit 44 are connected to the external input terminals 11, 12 and 13. Therefore, the input voltage signals Vb, Vc and Vd of the input voltage signals Va, Vb, Vc and Vd are input into the amplification unit 41, the input voltage signals Va, Vc and Vd are input into the amplification unit 42, the input voltage signals Va, Vb and Vd are input into the amplification unit 43, and the input voltage signals Va, Vb and Vc are input into the amplification unit 44.

The amplification units 41, 42, 43 and 44 are basically similar to the amplification units 31, 32 and 33 shown in FIG. 1, and each unit includes, for example, three voltage-to-current converters and one load. Three input voltage signals input into each of the amplification units 41, 42, 43 and 44 are converted into current signals by the voltage-to-current converter, then currents are added, and a current added signal is further converted into an output voltage signal.

That is, in the amplification unit 41, the current added signal corresponding to Vb, Vc and Vd is converted into the output voltage signal, and led to an internal output terminal 414. In the amplification unit 42, the current added signal corresponding to Va, Vc and Vd is converted into the output voltage signal, and led to an internal output terminal 424. In the amplification unit 43, the current added signal corresponding to Va, Vb and Vd is converted into the output voltage signal, and led to an internal output terminal 434. In the amplification unit 44, the current added signal corresponding to Va, Vb and Vc is converted into the output voltage signal, and led to an internal output terminal 444. The output voltage signals from the internal output terminals 414, 424, 434 and 444 of the amplification units 41, 42, 43 and 44 are led to the external output terminals 21, 22, 23 and 24.

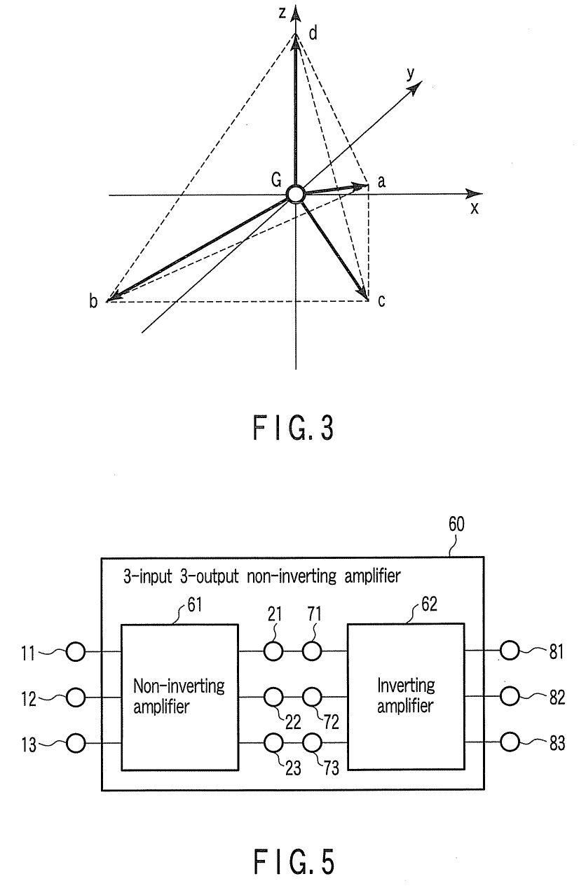

If a two-dimensional vector signal such as an I/Q orthogonal signal is handled as four signals, two differential signals are sufficient. Therefore, a signal line can simply be replaced to obtain an inverted signal and a non-inverted signal. However, in a case where four signals a, b, c and d indicate a three-dimensional vector as shown in FIG. 3, coordinate axes indicated by voltages (Va, Vb, Vc and Vd) of the respective signals a, b, c and d are separate, and an inverted signal is not present.

In the present embodiment, in the same manner as in the balanced three-phase signal described in the first embodiment, the inverted signal is obtained by use of a characteristic that a voltage average value of the four-phase input voltage signals Va, Vb, Vc and Vd is (Va+Vb+Vc+Vd)/4=0, that is, a voltage sum is Va+Vb+Vc+Vd=0. That is, the amplification units 41, 42, 43 and 44 amplify inverted signals −Va=Vb+Vc+Vd, −Vb=Va+Vc+Vb, −Vc=Va+Vb+Vb and −Vd=Va+Vb+Vc of Va, Vb and Vc and Vd, whereby the four-input four-output non-inverting amplifier 40 having a one-stage constitution can be realized.

### Third Embodiment

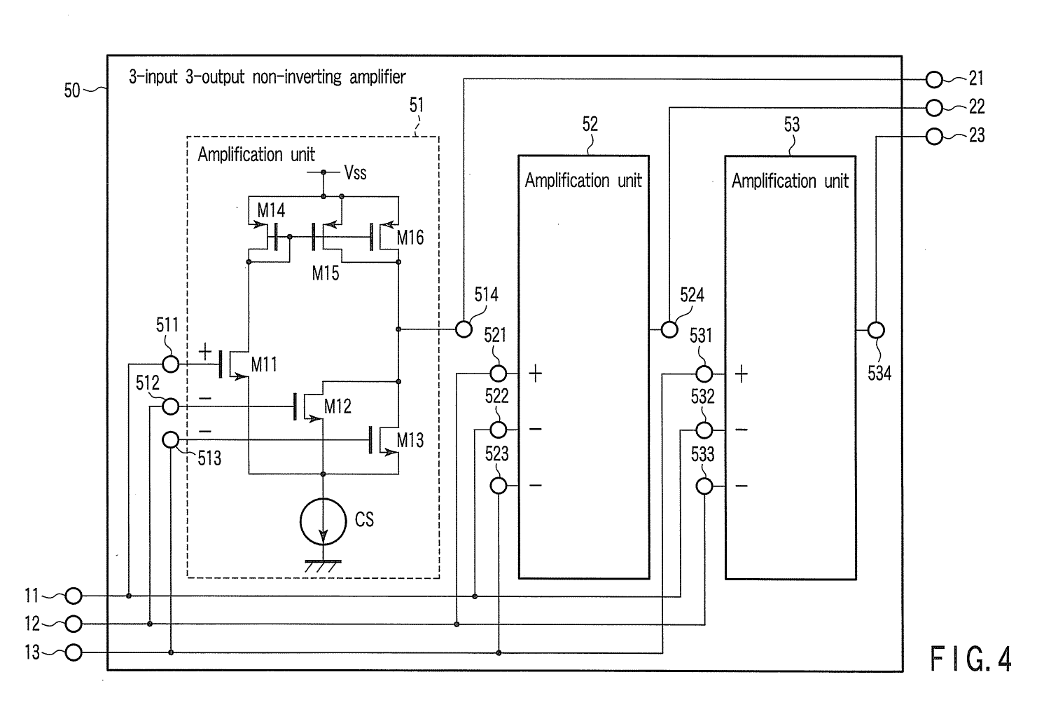

FIG. 4 shows a three-input three-output non-inverting amplifier according to a third embodiment of the present invention. An amplifier 50 includes n=3 external input terminals 11, 12 and 13, three external output terminals 21, 22 and 23, and three amplification units 51, 52 and 53. In the same manner as in the first embodiment, input voltage signals (Va, Vb and Vc) having a constant average value of voltages (a sum of voltages is constant) are input into the external input terminals 11, 12 and 13.

The amplification units 51, 52 and 53 include one non-inverting input terminal, n−1=2 inverting output terminals, and one internal output terminal. That is, the amplification unit 51 includes a non-inverting input terminal 511, inverting input terminals 512 and 513, and an internal output terminal 514, the amplification unit 52 includes a non-inverting input terminal 521, inverting input terminals 522 and 523, and an internal output terminal 524, and the amplification unit 53 includes a non-inverting input terminal 531, inverting input terminals 532 and 533, and an internal output terminal 534.

Each of the non-inverting input terminals 511, 521 and 531 of the amplification units 51, 52 and 53 is connected to one of external input terminals in a different combination for each of the amplification units 51, 52 and 53. Accordingly, the inverting input terminals 512, 513, 522, 523, 532 and 533 are connected to the remaining n−1 external input terminals. That is, the non-inverting input terminals 511, 521 and 531 are connected to external input terminals 11, 12 and 13, respectively. The inverting input terminals 512 and 513 are connected to the external input terminals 12 and 13, the inverting input terminals 522 and 523 are connected to the external input terminals 11 and 13, and the inverting input terminals 532 and 533 are connected to the external input terminals 11 and 12.

An input voltage signal Va input into the non-inverting input terminal 511 of the amplification unit 51 is converted into a current signal by a voltage-to-current converter (e.g., a grounded source amplifier including an N-type MOS transistor M11), and input voltage signals Vb and Vc input into the inverting input terminals 512 and 513 are converted into current signals by voltage-to-current converters (e.g., grounded source amplifiers including N-type MOS transistors M12 and M13, respectively).

The gates of transistors M11, M12 and M13 are connected to the internal input terminals 511, 512, and 513, respectively, and the sources of transistors M11, M12 and M13 are connected to a current source CS. The drains of transistors M11, M12 and M13 are connected to a current mirror circuit as an active load. The current mirror circuit includes P-type MOS transistors M14, M15 and M16. Here, the drain and the gate of the diode-connected transistor M11 are current input ends of the current mirror circuit, and the common drain of transistors M12 and M13 is a current output end of the current mirror circuit.

A drain current signal of the transistor M11 is turned back by the current mirror circuit, and output from the current output end of the current mirror circuit. On the other hand, drain current signals of transistors M12 and M13 are added, when the drains of transistors M12 and M13 are connected to each other. The current output end of the current mirror circuit and the common drains of transistors M12 and M13 are connected in common to the internal output terminal 514. Therefore, from the internal output terminal 514, an output voltage signal k{Va−(Vb+Vc)}=k2Va is obtained in which a difference current signal between a current added signal obtained by adding the drain current signals of transistors M12 and M13 and the drain current signal of the transistor M11 is subjected to current-to-voltage conversion. In this case, k is an amplification factor.

Similarly, k{Vb−(Va+Vc)}=k2Vb is obtained from the internal output terminal 524 of the amplification unit 52, and k{Vc−(Va+Vc)}=k2Vc is obtained from the internal output terminal 534 of the amplification unit 53. The output voltage signals from the internal output terminals 514, 524 and 534 of the amplification units 51, 52 and 53 are led to the external output terminals 21, 22 and 23.

Thus, even in the present embodiment, the non-inverting amplifier 50 having a one-stage constitution can be realized with respect to a balanced three-phase signal in the same manner as in the first embodiment. This non-inverting amplifier 50 input all the balanced three-phase signals (Va, Vb and Vc) into all the amplification units 51, 52 and 53. Moreover, currents of transistors M11, M12 and M13 are limited to a constant value by the current source CS connected to the common source of transistors M11, M12 and M13 which are the voltage-to-current converters for Va, Vb and Vc. Therefore, the common mode gain is minimized, that is, the common mode rejection ratio can be increased, and the output voltage signal having a small common mode fluctuation can be obtained.

### Fourth Embodiment

FIG. 5 shows a three-input three-output inverting amplifier 60 having a two-stage constitution according to a fourth embodiment of the present invention. This inverting amplifier 60 includes a three-input three-output non-inverting amplifier 61 and a three-input three-output inverting amplifier 62 connected to each other in cascade, and the non-inverting amplifier 30 shown in FIG. 1 or the non-inverting amplifier 50 shown in FIG. 4 is used as the three-input three-output non-inverting amplifier 61 of an input stage. External output terminals 21, 22 and 23 of the non-inverting amplifier 61 of the input stage are connected to input terminals 71, 72 and 73 of the inverting amplifier 62 of an output stage, and output terminals 81, 82 and 83 of the inverting amplifier 62 are output terminals of the three-input three-output inverting amplifier 60.

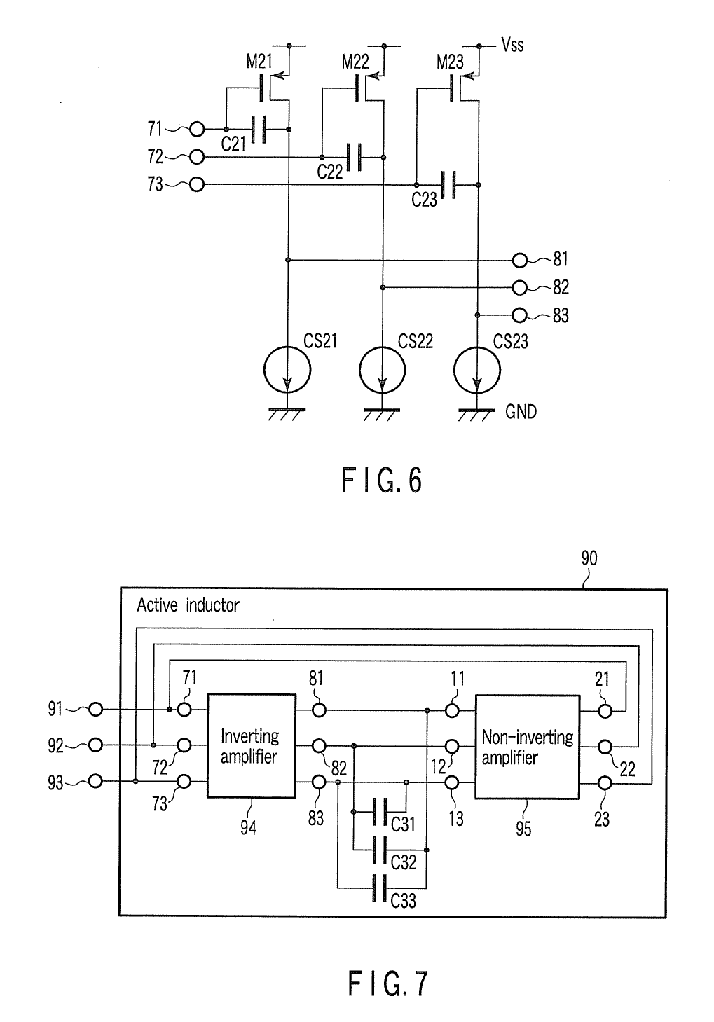

In the inverting amplifier 62 of the output stage, for example, a grounded source amplifier including PMOS transistors M21, M22 and M23 shown in FIG. 6 is used. The gates of transistors M21, M22 and M23 are connected to the input terminals 71, 72 and 73, the sources of transistors M21, M22 and M23 are connected to a power source Vss, and the drains of transistors M21, M22 and M23 are connected to current sources CS21, CS22 and CS23 and the output terminals 81, 82 and 83.

The two-stage amplifier shown in FIG. 5 includes an advantage that a comparatively large output signal amplitude can be secured even with a low power voltage, but parasitic oscillation is easily caused. Therefore, it is preferable that, as shown in FIG. 6, capacitors C21, C22 and C23 for phase compensation are inserted between inputs and outputs of the inverting amplifier 62, that is, between the input terminals 71, 72 and 73 and the output terminals 81, 82 and 83.

### Fifth Embodiment

FIG. 7 shows a three-terminal active inductor 90 as an example of an active inductor according to a fifth embodiment of the present invention. The three-terminal active inductor 90 is an active inductor which functions with respect to balanced three-phase signals, and includes three external connection terminals 91, 92 and 93 into which the balanced three-phase signals are to be input. The external connection terminals 91, 92 and 93 are connected to input terminals 71, 72 and 73 of an inverting amplifier 94, and output terminals 81, 82 and 83 of the inverting amplifier 94 are connected to external input terminals 11, 12 and 13 of a non-inverting amplifier 95.

As the non-inverting amplifier 95, the non-inverting amplifier 30 shown in FIG. 1, the non-inverting amplifier 50 shown in FIG. 4 or the non-inverting amplifier shown in FIG. 5 is used. External output terminals 21, 22 and 23 of the non-inverting amplifier 95 are connected to the input terminals 71, 72 and 73 of the inverting amplifier 94.

As an inductor to be realized on an integrated circuit, a gyrator using a voltage controlled current source and an active inductor using a capacitor are known. To realize the gyrator, a voltage controlled current source having a different polarity of an output current is required. In the voltage controlled current source using a differential circuit, the polarity of the output current can be inverted by replacement of a signal line, but such a technique is not effective with respect to the balanced three-phase signal. On the other hand, as shown in FIG. 7, when the non-inverting amplifier 95 having the constitution shown in FIG. 1, 4 or 5 is connected to the inverting amplifier 94 in cascade, the gyrator can be realized with respect to the balanced three-phase signal, whereby the three-terminal active inductor 90 can be realized.

In FIG. 7, voltages on the external connection terminals 91, 92 and 93 are converted into currents by the inverting amplifier 94. The output current from the inverting amplifier 94 is converted into a voltage by capacitors C31, C32 and C33. With regard to terminal voltages of the capacitors C31, C32 and C33, a signal amplitude decreases owing to characteristics of the capacitors, when a frequency is high. Moreover, a phase of each terminal voltage deviates as much as 90° from that of a signal current. The terminal voltages of the capacitors C31, C32 and C33 are fed back as the current signals to the input terminals 71, 72 and 73 by the non-inverting amplifier 95. As viewed from the external connection terminals 91, 92 and 93, when the frequency is high, the current changes a little as compared with a change of the voltage, and the current having a phase different as much as 90° from that of the voltage flows through the terminals.

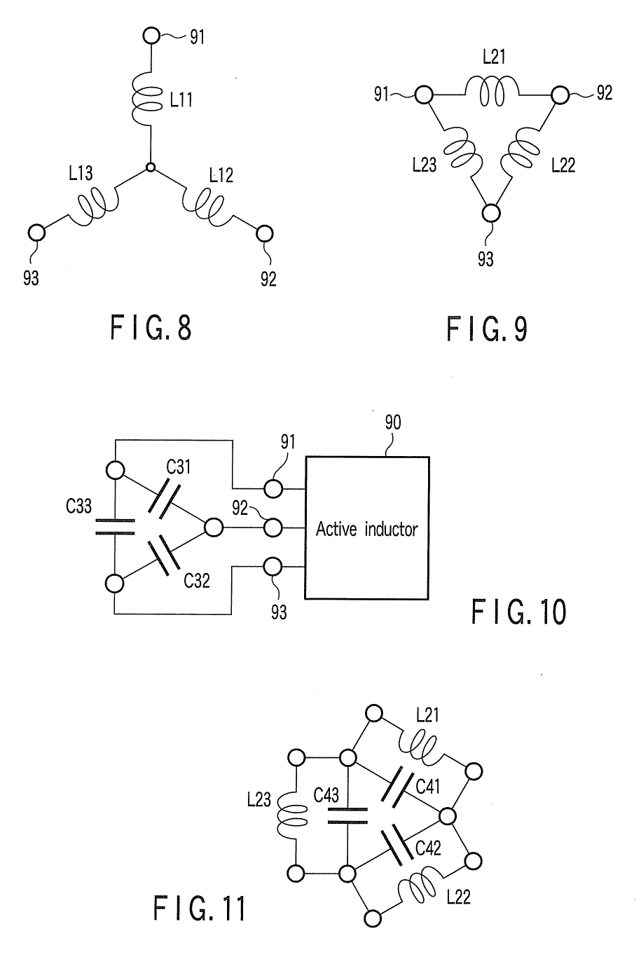

FIGS. 8 and 9 show equivalent circuit examples of the three-terminal active inductor 90 shown in FIG. 7. In the three-phase active inductor 90 of FIG. 7, as methods for representing an equivalent circuit, there are representation by Y-type connection shown in FIG. 8, and representation by Δ-type connection shown in FIG. 9. That is, in the equivalent circuit of FIG. 8, each of external connection terminals 91, 92 and 93 are connected to one terminal of each of inductors L11, L12 and L13, and the other end of each of the inductors L11, L12 and L13 is connected in common. On the other hand, in the equivalent circuit of FIG. 9, inductors L21, L22 and L23 are connected among external connection terminals 91, 92 and 93.

### Sixth Embodiment

FIG. 10 shows a three-terminal filter (a resonance circuit) according to a sixth embodiment of the present invention. The filter is realized using an active inductor 90 and capacitors. Three capacitors C31, C32 and C33 are connected in a A-type among external connection terminals 91, 92 and 93 of the three-terminal active inductor 90 shown in FIG. 7. The filter of FIG. 10 includes an equivalent circuit shown in FIG. 11, and inductances L21, L22 and L23 in the equivalent circuit of the active inductor 90 shown in FIG. 9 are connected to capacitors C41, C42 and C43 in parallel.

As also apparent from the equivalent circuit of FIG. 11, an LC resonance circuit is connected among the external connection terminals 91, 92 and 93 in the filter (the resonance circuit) of FIG. 10, so that the filter has characteristics that a low impedance is exerted in the vicinity of a direct current or at a very high frequency and that a high impedance is exerted only at a specific frequency band in the vicinity of a resonant frequency.

### Seventh Embodiment

The above-described amplifiers and the filters in the first to sixth embodiments are applicable to, for example, an analog signal processing circuit of a radio communication device which modulates both amplitude and phase. In this case, a chip area can be reduced, and accordingly a necessary function can be provided inexpensively.

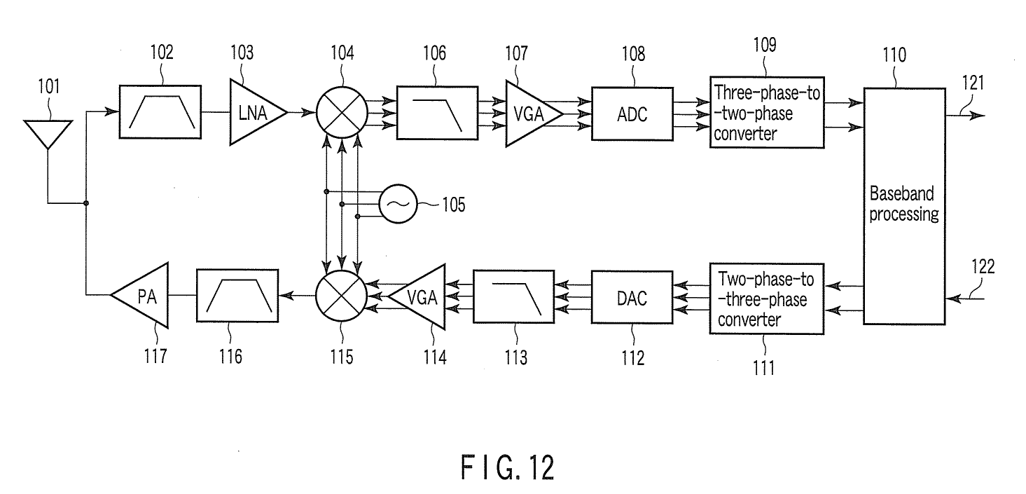

FIG. 12 shows a radio communication device in an seventh embodiment of the present invention to which the amplifier and the filter in the first to sixth embodiments are applied. First, a reception side will be described. A reception signal obtained by an antenna 101 receiving an RF signal is input into a low-noise amplifier 103, after a channel is roughly selected by a high-frequency filter 102 (e.g., a bandpass filter). A receiver includes the antenna 101, the high-frequency filter 102, and the low-noise amplifier 103.

An output signal of the low-noise amplifier 103 is input into a vector multiplier 104. A three-phase local signal generation unit 105 supplies three-phase local signals to the vector multiplier 104. A demodulator includes the vector multiplier 104 and the three-phase local signal generation unit 105. Three-phase baseband signals in the vicinity of a direct current appear in outputs of the vector multiplier 104.

In a case where the vector multiplier 104 is used as a demodulator similar to a conventional quadrature demodulator, a modulated signal represented by the following equation is input into an RF input terminal of the vector multiplier 104:

I(t)cos ωt+Q(t)sin ωt (1)

wherein I(t) denotes an in-phase signal (I-signal), and Q(t) denotes a quadrature-phase signal (Q-signal).

On the other hand, three-phase local signals represented by the following equations are input from the three-phase local signal generation unit 105 into local input terminals of the vector multiplier 104:

$$\begin{matrix}cos ω t \\ cos ( ω t + \frac{2}{3} π ) = cos ω t cos \frac{2}{3} π - sin ω t sin \frac{2}{3} π \\ cos ( ω t - \frac{2}{3} π ) = cos ω t cos \frac{2}{3} π + sin ω t sin \frac{2}{3} π\end{matrix} \} \qquad ( 2 )$$

The vector multiplier 104 multiplies the modulated signal of Equation (1) by the three-phase local signals of Equation (2). At this time, low-frequency components of output signals obtained in output terminals of the vector multiplier 104 are given by the following equation.

$$\frac{I ( t )}{2} \\ \frac{- I ( t )}{4} - \frac{\sqrt{3} Q ( t )}{4} \\ \frac{- I ( t )}{4} + \frac{\sqrt{3} Q ( t )}{4} \qquad ( 3 )$$

In Equation (3), the I-signal I(t) can be extracted by passing an output signal from a first output terminal of the vector multiplier 104 through a low-pass filter. As to the Q-signal Q(t), after passing output signals from second and third output terminals of the vector multiplier 104 through the low-pass filter, respectively, the following calculation may be performed by an operational unit including an analog or digital circuit.

$$( \frac{- I ( t )}{4} + \frac{\sqrt{3} Q ( t )}{4} ) - ( \frac{- I ( t )}{4} - \frac{\sqrt{3} Q ( t )}{4} ) = \frac{\sqrt{3} Q ( t )}{2} \qquad ( 4 )$$

In the same manner as in a usual direct conversion receiver, a baseband filter 106 (e.g., a low-pass filter) selectively extracts necessary frequency components, for example, low-frequency components of Equation (3) from the output signals of the vector multiplier 104. Output signals of the baseband filter 106 are amplified into signals having an amplitude suitable for analog-to-digital conversion by a variable gain amplifier 107, and thereafter input into an analog-to-digital converter 108. Three-phase digital baseband signals are output from the analog-to-digital converter 108.

The three-phase digital baseband signals are input into a three-phase to two-phase converter 109. The three-phase to two-phase converter 109 converts the three-phase digital baseband signals into usual two I and Q phase digital baseband signals as two-phase signals by, for example, calculation shown by Equation (4). The two-phase digital baseband signals are sent to a baseband processing section 110. The baseband processing section 110 decodes the two-phase digital baseband signals to obtain reception data 121.

Next, a transmission side will be described. The baseband processing section 110 outputs two-phase digital baseband signals of I and Q generated in accordance with transmission data 122. The two-phase digital baseband signals are converted into the three-phase digital baseband signals by processing the reverse that of the three-phase to two-phase converter 109 by a two-phase to three-phase converter 111. The three-phase digital baseband signals are converted into analog signals (analog modulation signals) by a digital-to-analog converter 112, respectively.

A baseband filter 113 (e.g., a low-pass filter) removes high-pass side unnecessary components from the analog modulation signals output from the digital-to-analog converter 112. Furthermore, a variable gain amplifier 114 amplifies the signals into appropriate amplitudes, and the signals are input into a vector multiplier 115. Three-phase local signals are supplied from the three-phase local signal generation unit 105 to the vector multiplier 115. A modulator includes the vector multiplier 115 and the three-phase local signal generation unit 105. A high-frequency modulated signal is output from the vector multiplier 115.

A high-frequency filter (e.g., a band pass filter) 116 removes a higher harmonic component from the modulated signal output from the vector multiplier 115. An output signal of the high-frequency filter 116 is amplified into a necessary power by a power amplifier 117, and supplied to the antenna 101. Accordingly, the antenna 101 transmits an RF signal. A transmitter includes the high-frequency filter 116, the power amplifier 117, and the antenna 101.

Here, the amplifiers described with reference to FIGS. 1 to 7 are applicable to, for example, the variable gain amplifiers 107 and 114 shown in FIG. 12. On the other hand, the three-phase filters described with reference to FIGS. 8 to 11 are applicable to the baseband filters 106 and 113 shown in, for example, FIG. 12.

In a case where the amplifier or the filter in the above-described embodiments of the present invention is used as the analog signal processing circuit of the radio communication device, which modulates both amplitude and phase, the chip area of the integrated circuit can be reduced, and accordingly, the necessary function can be provided inexpensively. Even in a case where the amplifier or the filter is used as a signal amplifying amplifier such as an acceleration sensor or an analog vector signal processing circuit such as a filter for removing an unnecessary signal, the components and the chip area of the integrated circuit can be reduced, and an inexpensive device can be provided as compared with the differential system.

When the non-inverting amplifier according to the embodiment of the present invention is used, the inverted signal and the non-inverted signal can be obtained with a simple circuit constitution, so that a chip area and a current consumption can accordingly be reduced. When the chip area can be reduced, cost can accordingly be reduced. When a power consumption can be reduced, a lightweight and small-sized cell can be used as a power source.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A non-inverting amplifier comprising:
n external input terminals which receive n (n≧3) input voltage signals having a constant sum of voltages, respectively;
n amplification units each including:
n−1 internal input terminals connected to n−1 terminals of the n external input terminals in a different combination for each of the amplification units;
n−1 voltage-to-current converters which convert input voltage signals from the internal input terminals into current signals; and
a load which converts an added current signal obtained by adding up the current signals into an output voltage signal; and
n external output terminals which output n output voltage signals from the n amplification units.

2. The amplifier according to claim 1, wherein each of the voltage-to-current converters includes a transistor having a control terminal connected to the internal input terminal, a first main terminal connected in common to the load, and a second main terminal connected to a reference potential point.

3. A non-inverting amplifier comprising:
n external input terminals which receive n (n≧3) input voltage signals having a constant sum of voltages, respectively;
n amplification units each including:
a non-inverting input terminal connected to one terminal of the external input terminals in a different combination for each of the amplification units;
n−1 inverting input terminals connected to the remaining n−1 terminals of the external input terminals;
a first voltage-to-current converter which converts an input voltage signal from the non-inverting input terminal into a first current signal;
n−1 second voltage-to-current converters which convert input voltage signals from the inverting input terminals into second current signals, respectively; and
a load which converts, into an output voltage signal, a difference current signal between an added current signal obtained by adding up the second current signals and the first current signal; and
n external output terminals which output n output voltage signals from the n amplification units, respectively.

4. The amplifier according to claim 3, wherein the amplification unit further includes a current source,
the load includes a current mirror circuit having a current input end and a current output end connected to the external output terminal,
the first voltage-to-current converter includes a first transistor having a control terminal connected to the non-inverting input terminal, a first main terminal connected to the current input end and a second main terminal connected to the current source, and
the second voltage-to-current converter includes a second transistor having a control terminal connected to the inverting input terminal, a first main terminal connected to the current output end and a second main terminal connected in common to the current source.

5. An amplifier comprising:
the non-inverting amplifier according to claim 1; and
an inverting amplifier connected to the non-inverting amplifier in cascade.

6. An amplifier comprising:
the non-inverting amplifier according to claim 3; and
an inverting amplifier connected to the non-inverting amplifier in cascade.

7. An active inductor comprising:
n (n≧3) external connection terminals;
n (n≧3) first voltage-to-current conversion units which convert voltages on the external connection terminals into currents;
n (n≧3) capacitors which generate terminal voltage signals corresponding to the currents and having a constant sum of voltages; and
a second voltage-to-current conversion unit which converts the terminal voltage signals into feed back currents fed back to the first voltage-to-current conversion units.

8. The active inductor according to claim 7, wherein the first voltage-to-current conversion units include inverting amplifiers.

9. The active inductor according to claim 7, wherein the second voltage-to current conversion unit includes n external input terminals which receive the terminal voltage signals as input voltage signals; n amplification units; and n external output terminals which output the output voltage signals, and
each of the amplification units is a non-inverting amplifier including n−1 internal input terminals connected to n−1 terminals of the n external input terminals in a different combination for each of the amplification units, n−1 voltage-to-current converters which convert input voltage signals from the internal input terminals into current signals and which output the converted signals, and a load which converts an added current signal obtained by adding up the current signals into the output voltage signal.

10. The active inductor according to claim 7, wherein the second voltage-to current conversion unit includes n external input terminals which receive the terminal voltages as input voltage signals; n amplification units; and n external output terminals which output the output voltage signals, and
each of the amplification units is a non-inverting amplifier including a non-inverting input terminal connected to one terminal of the external input terminals in a different combination for each of the amplification units, n−1 inverting input terminals connected to the remaining n−1 terminals of the external input terminals, a first voltage-to-current converter which converts an input voltage signal from the non-inverting input terminal into a first current signal, n−1 second voltage-to-current converters which convert input voltage signals from the inverting input terminals into second current signals, respectively, and a load which converts, into the output voltage signal, a difference current signal between an added current signal obtained by adding up the second current signals and the first current signal.

11. A filter which includes the active inductor according to claim 7.

12. The filter according to claim 11, which further includes n capacitors connected among the n external connection terminals.

13. A radio communication device comprising:
a reception unit which receives a radio frequency signal to generate a received signal;
a demodulation unit which demodulates the received signal to generate first, second and third baseband signals;
a baseband amplifier including the non-inverting amplifier according to claim 1 which receives the first, second and third baseband signals, and amplifies the first, second and third baseband signals, to output first, second and third output signals;
an analog-to-digital converter which converts the first, second and third output signals into digital baseband signals; and
a processing unit to perform decode processing on the digital baseband signals.

14. A radio communication device comprising:
a reception unit which receives a radio frequency signal to generate a received signal;
a demodulation unit which demodulates the received signal to generate first, second and third baseband signals;
a baseband amplifier including the non-inverting amplifier according to claim 3 which receives the first, second and third baseband signals, and amplifies the first, second and third baseband signals, to output first, second and third output signals;
an analog-to-digital converter which converts the first, second and third output signals into digital baseband signals; and
a processing unit perform decode processing on the digital baseband signals.

15. A radio communication device comprising:
a processing unit which processes data to be transmitted, to generate first, second and third digital baseband signals;
a digital-to-analog converter which converts the first, second and third digital baseband signals into first, second and third analog baseband signals;
a baseband amplifier including the non-inverting amplifier according to claim 1 which amplifies the first, second and third analog baseband signals to output first, second and third output signals;
a modulation unit which modulates the first, second and third output signals to output a radio frequency signal; and
a transmission unit which transmits the radio frequency signal.

16. A radio communication device comprising:
a processing unit which processes data to be transmitted, to generate first, second and third digital baseband signals;
a digital-to-analog converter which converts the first, second and third digital baseband signals into first, second and third analog baseband signals;
a baseband amplifier including the non-inverting amplifier according to claim 3 which amplifies the first, second and third analog baseband signals to output first, second and third output signals;
a modulation unit which modulates the first, second and third output signals to output a radio frequency signal; and
a transmission unit which transmits the radio frequency signal.

17. A radio communication device comprising:
a reception unit which receives a radio frequency signal to generate a received signal;
a demodulation unit which demodulates the received signal to generate first, second and third baseband signals;
the filter according to claim 11 which receives the first, second and third baseband signals, and amplifies a desired frequency component of the first, second and third input signals, to output first, second and third output signals;
an analog-to-digital converter which converts the first, second and third output signals into digital baseband signals; and
a processing unit to perform decode processing on the digital baseband signals.

18. A radio communication device comprising:
a processing unit which processes data to be transmitted, to generate first, second and third digital baseband signals;
a digital-to-analog converter which converts the first, second and third digital baseband signals into first, second and third analog baseband signals;
the filter according to claim 11 which receives the first, second and third analog baseband signals, and removes unnecessary higher harmonic components from the first, second and third input signals, to output first, second and third output signals;
a modulation unit which modulates the first, second and third output signals to output a radio frequency signal; and
a transmission unit which transmits the radio frequency signal.
